(19) United States
(12) Patent Application Publication
(10) Pub. No.: US 2022/0118551 A1
(43) Pub. Date: Apr. 21, 2022

(54) METHOD FOR PRODUCING THREE-DIMENSIONAL SILICON CARBIDE-CONTAINING OBJECTS

(71) Applicant: PSC Technologies GmbH, Berlin (DE)

(72) Inventor: Siegmund GREULICH-WEBER, Bad Lippspringe (DE)

(21) Appl. No.: 17/288,768

(22) PCT Filed: Nov. 5, 2019
(86) PCT No.: PCT/EP2019/080240

§ 371 Date: Apr. 26, 2021

(30) Foreign Application Priority Data
Nov. 13, 2018 (DE) 10 2018 128 434.9

(51) Int. Cl. B23K 26/144; B33Y 10/00; B33Y 70/00; B33Y 80/00; B23K 26/12; B23K 26/14; B23K 26/34; B22F 10/16

(52) U.S. Cl. CPC B23K 26/144; B33Y 10/00; B33Y 70/00; B33Y 80/00; B23K 2103/52; B23K 26/1462; B23K 26/34; B22F 10/16; B23K 26/123

(57) ABSTRACT

Subject-matter of the invention is a method of applying silicon carbide-containing materials to a substrate surface, and an apparatus for carrying out the method.

The present invention relates to the technical field of generative manufacturing processes, in particular additive manufacturing.

In particular, the present invention relates to a method for applying silicon carbide-containing materials to a substrate, in particular for site-selective application to a substrate.

Furthermore, the present invention relates to silicon carbide-containing objects obtainable by the method according to the invention.

Finally, the present invention relates to an apparatus for carrying out the method.

Generative manufacturing processes, also known as additive manufacturing (AM), are methods for the rapid production of models, patterns, tools and products from formless materials such as liquids, gels, pastes or powders.

Originally, the terms 3D printing or rapid prototyping were generally used for generative manufacturing processes, in particular additive manufacturing. However, these terms are now only used for special configurations of generative manufacturing processes. Generative manufacturing processes are used for the production of objects from inorganic materials, in particular metals and ceramics, as well as from organic materials.

For the production of objects from inorganic materials, high-energy methods such as selective laser melting, electron beam melting or buildup welding are preferably used, since the reactants or precursors used only react or melt at higher energy input.

In principle, additive manufacturing enables the rapid production of highly complex components, but in particular the production of components from inorganic materials poses a number of challenges for both the reactant and the product materials: for example, the reactants may only react in a specified manner under the influence of energy, and in particular, disruptive side effects must be ruled out.

In addition, for example, no segregation of the products or phase separation or even decomposition of the products may occur under the influence of energy.

A material that is extremely interesting and versatile for the production of high-performance ceramics and for semiconductor applications is silicon carbide, also known as carborundum. Silicon carbide, with the chemical formula SiC, has an extremely high hardness as well as a high sublimation point and is often used as an abrasive or as an insulator in high-temperature reactors. Silicon carbide also forms compounds with a variety of elements and alloys or alloy-like compounds, which often comprise advantageous material properties, such as high hardness, high durability, low weight, and low oxidation sensitivity even at high temperatures.

The properties of the porous silicon carbide material produced via conventional sintering processes do not match those of compact crystalline silicon carbide, so the advantageous properties of silicon carbide cannot be fully exploited.

In addition, silicon carbide does not melt at high temperatures—depending on the type of crystal—in the range from 2,300 to 2,700° C., but sublimates, i.e. changes from the solid to the gaseous aggregate state. This makes silicon carbide unsuitable in particular for additive manufacturing processes such as laser melting.

Due to the versatile applicability of silicon carbide, or materials containing silicon carbide, and the large number of positive application properties, attempts have nevertheless been made to process silicon carbide by means of additive manufacturing processes.

For example, DE 10 2015 105 085.4 describes a method for the production of bodies from silicon carbide crystals, wherein the silicon carbide is obtained in particular by laser radiation from suitable carbon and silicon-containing precursor compounds in a powder bed process following selective laser melting (SLM).

The method described in DE 10 2015 105 085.4 is certainly suitable for obtaining objects from silicon carbide crystals, but the powder bed process always requires a relatively large amount of precursor material to be kept on hand, which is not used, is furthermore contaminated by by-products in the course of the manufacturing process and consequently cannot be fully used without reprocessing in further manufacturing processes.

One method suitable for the production of layers or three-dimensional objects is deposition welding. In deposition welding, material is applied to a substrate or workpiece by melting the substrate or workpiece while simultaneously applying a material. A special form of deposition welding is laser deposition welding, with which the thermal energy provided for the melting process is supplied by a laser. With deposition welding or laser deposition welding, three-dimensional objects and coatings can be produced in a targeted manner, making full use of reactant materials, i.e. without unused residues. In addition, it is also possible to join or, for example, repair parts by replacing a loss of material with deposition welding. Typically, laser deposition welding is used for the deposition of metallic materials.

Up to now, it has not been possible to process ceramic materials, in particular those containing silicon carbide, by means of deposition welding, since silicon carbide does not melt at high temperatures—as mentioned above—but sublimates.

Thus, the prior art still lacks a method for the targeted production of objects from silicon carbide and silicon carbide-containing materials using raw materials as efficiently as possible.

It is thus an object of the present invention to avoid, or at least to mitigate, the previously described disadvantages and problems associated with the prior art.

In particular, it is an object of the present invention to provide a method which makes it possible to deposit or produce silicon carbide-containing materials or structures from silicon carbide-containing materials in a site-selective and locally limited manner on a substrate.

In addition, a further object of the present invention is to provide a method which enables components or objects made of silicon carbide-containing materials to be produced or repaired by targeted material deposition.

A subject-matter of the present invention according to a first aspect of the present invention is a method for applying silicon carbide-containing materials to a substrate according to claim 1; further advantageous embodiments of this aspect of the invention are subject of the respective dependent claims.

Further subject-matter of the present invention according to a second aspect of the present invention is a silicon carbide-containing three-dimensional object according to claim 13.

Finally, a further subject-matter of the present invention according to a third aspect of the present invention is an apparatus for the site-selective deposition of silicon carbide-containing materials according to claim 14; further, advantageous embodiments of this aspect of the invention are subject of the respective dependent claims.

It goes without saying that special configurations mentioned below, in particular special embodiments or the like, which are described only in the context of one aspect of the invention, also apply accordingly with respect to the other aspects of the invention, without this requiring express mention.

Furthermore, in the case of all relative or percentage, in particular weight-related, indications of quantity mentioned below, it should be noted that these are to be selected by the skilled person within the scope of the present invention in such a way that 100% or 100 wt % always results in the sum of the ingredients, additives or auxiliary substances or the like. However, this is self-evident for the person skilled in the art.

In addition, it applies that all parameter data or the like mentioned in the following can basically be determined with standardized or explicitly stated determination procedures or determination methods familiar to the skilled person.

With this proviso stated, the subject-matter of the present invention will be explained in more detail below.

Thus, the subject-matter of the present invention—according to a first aspect of the present invention—is a method for applying silicon carbide-containing materials to a substrate surface, wherein a gaseous, liquid or powdery precursor material containing a silicon source and a carbon source is gasified and/or decomposed by the action of energy and at least a part of the decomposition products is deposited site-selectively on the substrate surface as a silicon carbide-containing material.

The method according to the present invention permits the generation of high-resolution and detailed three-dimensional structures, i.e. the course of contours, such as corners or edges, is highly precise and in particular free of ridges.

In the context of the present invention, it is furthermore possible in particular to obtain objects in the form of compact solids which do not comprise a porous structure but consist of crystalline silicon carbide-containing materials. The materials and three-dimensional objects made of silicon carbide-containing materials obtainable by the method according to the invention thus possess in their material properties almost the properties of crystalline silicon carbide or silicon carbide alloys.

In particular, the method according to the invention allows very fast and low-cost production of three-dimensional silicon carbide-containing objects or layers and, in particular, does not require the application of pressure in order to provide compact non-porous or low-porosity materials and components.

The method according to the invention can be used both to apply layers of silicon carbide-containing materials to a substrate surface and to build up three-dimensional objects of silicon carbide-containing materials on the substrate surface, which can subsequently be removed again if necessary. Similarly, it is also possible to join components by applying silicon carbide-containing materials or to supplement material defects in components.

In the context of the present invention, a silicon carbide-containing compound is to be understood as a binary, ternary or quaternary inorganic compound whose molecular formula contains silicon and carbon. In particular, a silicon carbide-containing compound does not contain molecularly bound carbon, such as carbon monoxide or carbon dioxide; rather, the carbon is present in a solid-state structure.

In the context of the present invention, a silicon source or a carbon source means compounds that are capable of releasing silicon or carbon, respectively, under process conditions such that silicon carbide-containing compounds are formed. In this context, silicon and carbon need not be released in elemental form, but it is sufficient if they react under process conditions to form silicon carbide-containing compounds.

The silicon source, the carbon source or also the precursors for any doping or alloying elements can either be specific chemical compounds or, for example, their reaction products, in particular hydrolysates, as will be explained below.

In the context of the present invention, a substrate is to be understood as the material to which the preferably gaseous decomposition products of the precursor material are applied. In particular, a substrate in the context of the present invention is a three-dimensional or also a nearly two-dimensional structure with a surface on which the decomposition products of the precursor material are deposited. The substrate surface may be flat or contoured, in particular three-dimensionally structured. The substrate can comprise almost any three-dimensional shape. The substrate can thus be a carrier material on which silicon carbide-containing material is deposited layer by layer. The term substrate also includes, in particular, substrate materials which are partially coated with one or more layers of silicon carbide-containing materials. However, a substrate may also be a three-dimensional object joined to a second substrate, in particular another three-dimensional object, by deposited silicon carbide-containing material.

Now, with respect to the substrate on which the precursor material or its decomposition products are deposited, this can be selected from a variety of suitable materials. In the context of the present invention, it is possible that the substrate is selected from crystalline and amorphous substrates. According to a more preferred embodiment of the present invention, the substrate is an amorphous substrate. Particularly good results are obtained if the material is selected from carbon, in particular graphite, and ceramic materials, in particular silicon carbide, silicon dioxide, aluminum oxide, and metals and mixtures thereof. If the method according to the invention is used for the production of objects of silicon carbide-containing materials, the substrate often comprises several materials, in particular a support material and the at least partially built-up three-dimensional object of silicon carbide-containing material.

In the context of the present invention, the precursor material is preferably selected from gaseous, liquid or powdery precursor materials, wherein the use of solid, in particular powdery precursor materials is preferred. The liquid precursor material can be a homogeneous solution or also a dispersion, in particular also a solid-in-liquid dispersion.

In the context of the present invention, a precursor material is a chemical compound or a mixture of chemical compounds which react under process conditions to form the desired product materials, in particular materials containing silicon carbide.

The reaction to the target compounds can take place in a wide variety of ways. Advantageously, however, it is envisaged that the precursor compounds, by the action of energy, in particular by the action of a laser radiation, if necessary in the case of liquid or gaseous precursor materials are gasified and cleaved or decomposed and pass into the gas phase as reactive particles. Since silicon and carbon and, optionally, doping or alloying elements are present in the immediate proximity in the gas phase due to the special composition of the precursor, the silicon carbide or the doped silicon carbide or silicon carbide alloy, which sublimes only above 2,300° C., precipitates. In particular, crystalline silicon carbide absorbs laser energy much more poorly than the precursor granulate and conducts heat very well, so that a locally strictly limited deposition of the defined silicon carbide compounds takes place. On the other hand, undesirable components of the precursor compound preferably form stable gases, such as CO₂, HCl, H₂O, etc., and can be removed via the gas phase.

Within the scope of the present invention, it is provided in particular that the precursor material is a solid precursor material, in particular a precursor granulate. Particularly good results are obtained if the precursor granulate is not a powder mixture, in particular not a mixture of different precursor powders and/or granules. Preferably, within the scope of the invention, a homogeneous granulate, in particular precursor granulate, is used as precursor material for the method according to the invention.

In this way, by means of short exposure times to energy, in particular to laser beams, the precursor granulate can pass into the gas phase or the precursor compounds can react to form the desired target compounds, wherein it is not necessary to sublimate individual particles of different inorganic substances with particle sizes in the μm range, the constituents of which must then diffuse to form the corresponding compounds and alloys. Due to the homogeneous precursor granulate preferably used in the present invention, the individual building blocks, in particular elements, of the silicon carbide-containing target compound are homogeneously distributed and arranged in close proximity to one another, i.e. less energy is required for the production of the silicon carbide-containing compounds. This has the advantage that a multilayer structure of silicon carbide-containing material can be built without heating the top layer of the silicon carbide-containing material forming the substrate surface to temperatures at which silicon carbide sublimes.

According to a preferred embodiment of the present invention, the precursor granulate is obtainable from a precursor solution or a precursor dispersion, in particular a precursor sol. In the context of the present invention, the precursor granulate is thus preferably obtained in finely divided form from a liquid, in particular from a solution or dispersion. In this way, a homogeneous distribution of the individual components, in particular precursor compounds, can be achieved in the granulate, wherein preferably the stoichiometry of the silicon carbide-containing material to be produced is already preformed.

If the precursor granulate is obtainable from a solution or dispersion, in particular a gel, the precursor granulate is obtained by drying the precursor solutions or dispersions or the resulting gel.

Now, as far as the particle sizes of the precursor granulate are concerned, this can vary in wide ranges depending on the respective chemical compositions, the laser energy used as well as the properties of the material or object to be produced. In general, however, the precursor granulate comprises particle sizes in the range of 0.1 to 150 μm, in particular 0.5 to 100 μm, preferably 1 to 100 μm, more preferably 7 to 70 μm, particularly preferably 20 to 40 μm.

Particularly good results are obtained in the context of the present invention if the particles of the precursor granulate comprise a D60 value in the range of 1 to 100 μm, in particular 2 to 70 μm, preferably 10 to 50 μm, more preferably 21 to 35 μm. The D60 value for the particle size represents the limit below which the particle size of 60% of the particles of the precursor granulate lies, i.e. 60% of the particles of the precursor granulate comprise particle sizes which are smaller than the D60 value.

In this context, it can equally be provided that the precursor granulate comprises a bimodal particle size distribution. In this way, precursor granules with a high bulk density are in particular accessible.

As previously stated, the method according to the present invention is suitable for the production of layers or three-dimensional objects from a wide range of silicon carbide-containing compounds. In the context of the present invention, the silicon carbide-containing compound is typically selected from silicon carbide, doped silicon carbide, non-stoichiometric silicon carbides, doped non-stoichiometric silicon carbide, and silicon carbide alloys.

The method according to the invention can thus be used universally and is suitable for the production or deposition of a large number of different silicon carbide compounds, in particular in order to adjust their mechanical properties in a targeted manner.

In the context of the present invention, a non-stoichiometric silicon carbide is understood to be a silicon carbide which does not contain carbon and silicon in the molar ratio 1:1, but in ratios deviating therefrom. Typically, a non-stoichiometric silicon carbide in the context of the present invention comprises a molar excess of silicon.

In the context of the present invention, silicon carbide alloys are understood to be compounds of silicon carbide with metals, such as titanium or also other compounds, such as zirconium carbide or boron nitride, which contain silicon carbide in varying and highly fluctuating proportions. Silicon carbide alloys often form high-performance ceramics, which are characterized by particular hardness and temperature resistance.

If in the context of the present invention a non-stoichiometric silicon carbide is produced, the non-stoichiometric silicon carbide is usually a silicon carbide of the general formula (I)

SiC₁₋ₓ (I)

with
x=0.05 to 0.8, in particular 0.07 to 0.5, preferably 0.09 to 0.4, more preferably 0.1 to 0.3.

Such silicon carbides, which are rich in silicon, have a particularly high mechanical load-bearing capacity and are suitable for a wide range of applications as ceramics.

In the context of the present invention, when the silicon carbide-containing compound is a doped silicon carbide, the silicon carbide is typically doped with an element selected from the group consisting of nitrogen, phosphorus, arsenic, antimony, boron, aluminum, gallium, indium, and mixtures thereof. Preferably, the silicon carbide is doped with elements from the 13th and 15th groups of the periodic table of elements, which in particular allows the electrical properties of the silicon carbide to be specifically manipulated and adjusted. Such doped silicon carbides are in particular suitable for applications in semiconductor technology. As previously stated, the doped silicon carbide may be a stoichiometric silicon carbide or a non-stoichiometric silicon carbide, wherein the doping of stoichiometric silicon carbides is more preferably, since these are increasingly used in semiconductor technology.

If a doped silicon carbide is produced within the scope of the present invention, it has been well proven if the doped silicon carbide contains the doping element in amounts of 0.000001 to 0.0005 wt %, in particular 0.000001 to 0.0001 wt %, preferably 0.000005 to 0.0001 wt %, more preferably 0.000005 to 0.00005 wt %, based on the doped silicon carbide. Extremely small amounts of doping elements are thus completely sufficient for the specific adjustment of the electrical properties of the silicon carbide. The previously mentioned amounts of doping elements apply to both stoichiometric and non-stoichiometric silicon carbides.

When the silicon carbide-containing compound prepared in the present invention is a silicon carbide alloy, the silicon carbide alloy is usually selected from MAX phases, alloys of silicon carbide with elements, in particular metals, and alloys of silicon carbide with metal carbides and/or metal nitrides. Such silicon carbide alloys contain silicon carbide in varying and strongly fluctuating proportions. In particular, it may be envisaged that silicon carbide constitutes the main constituent of the alloys. However, it is also possible that the silicon carbide alloy contains silicon carbide only in small amounts.

Typically, the silicon carbide alloy comprises the silicon carbide in amounts of 10 to 95 wt. %, in particular 15 to 90 wt. %, preferably 20 to 80 wt %, based on the silicon carbide alloy.

In the context of the present invention, a MAX phase means in particular carbides and nitrides crystallizing in hexagonal layers of the general formula Mₙ₊₁AXn with n=1 to 3. M stands for an early transition metal from the third to sixth group of the periodic table of the elements, while A stands for an element from the 13th to 16th group of the periodic table of the elements. Finally, X is either carbon or nitrogen. In the context of the present invention, however, only those MAX phases are of interest whose molecular formula contains silicon carbide (SiC), i.e. silicon and carbon.

MAX phases comprise unusual combinations of chemical, physical, electrical and mechanical properties, as they exhibit both metallic and ceramic behavior, depending on the conditions. This includes, for example, high electrical and thermal conductivity, high resilience to thermal shock, very high hardness, and low coefficients of thermal expansion.

When the silicon carbide alloy is a MAX phase, it is preferred if the MAX phase is selected from Ti₄SiC₃ and Ti₃SiC.

In particular, the aforementioned MAX phases are highly resistant to chemicals as well as oxidation at high temperatures, in addition to the properties already described.

When the silicon carbide-containing compound is an alloy of silicon carbide, it has been well proven in case the alloy is an alloy of silicon carbide with metals, if the alloy is selected from alloys of silicon carbide with metals from the group of Al, Ti, V, Cr, Mn, Co, Ni, Zn, Zr and mixtures thereof.

If the alloy of silicon carbide is selected from alloys of silicon carbide with metal carbides and/or nitrides, it has been well proven if the alloys of silicon carbide with metal carbides and/or nitrides are selected from the group of boron carbides, in particular B₄C, chromium carbides, in particular Cr₂C₃, titanium carbides, in particular TiC, molybdenum carbides, in particular Mo₂C, niobium carbides, in particular NbC, tantalum carbides, in particular TaC, vanadium carbides, in particular VC, zirconium carbides, in particular ZrC, tungsten carbides, in particular WC, boron nitride, in particular BN, and mixtures thereof.

With regard to the temperatures at which precursor material gasifies and/or decomposes, it has been well proven that the precursor material, in particular the precursor granulate, is heated by the action of energy, in particular at least in certain areas, to temperatures in the range of 1,600 to 2,100° C., in particular 1,700 to 2,000° C., preferably 1,700 to 1,900° C. At the aforementioned temperatures, all components of the precursor material pass into the gas phase and the precursor materials are decomposed to form the desired reactive species, which then react to form the target compounds.

As stated previously, the use of solid, in particular powdery, precursor materials is preferred. However, the method according to the present invention can also be carried out with liquid or gaseous precursor materials.

When gaseous precursor materials are used in the context of the present invention, the precursor materials are decomposed by the action of energy and at least a portion of the decomposed precursor materials is deposited site-selectively on the substrate surface as a silicon carbide-containing material.

When liquid or solid, in particular powdery, precursor materials are used in the context of the present invention, they are typically gasified and decomposed, and then at least a portion of the decomposition products are deposited site-selectively on the substrate surface as silicon carbide-containing material. In the context of the present invention, a site-selective deposition means that the material is deposited locally limited to one location, which, however, may change in the course of the process.

Typically, the decomposition products are deposited on an area of 0.1 to 2 mm², in particular 0.5 to 1.5 mm², preferably 0.8 to 1.2 mm².

Thus, within the scope of the present invention, a locally sharply defined, site-selective deposition of a silicon carbide-containing material on a substrate surface is possible.

As the applicant has surprisingly found, the use of precursor materials comprising both a carbon and a silicon source makes it possible to produce three-dimensional objects of silicon carbide-containing materials or coatings of silicon carbide-containing materials in a method preferably based on deposition welding.

While the problem with the use of silicon carbide is that it sublimates and cannot be melted under normal conditions, it has been shown that by the use of suitable precursor materials, silicon carbide-containing materials, in particular in the form of layers, can be deposited on substrate surfaces by decomposition of the precursor materials in a site-selective manner from the gas phase. The layer of silicon carbide-containing material can cover the substrate surface completely or only in certain areas. In the case of repeated application of layers of silicon carbide-containing material, in the context of the present invention a layer of silicon carbide-containing material which has already been completed is added to the substrate, wherein its surface then forms the substrate surface at the areas where it covers a substrate material. In the context of the present invention, the substrate may comprise almost any three-dimensional structure.

Through repeated and site-selective application, it is possible to selectively apply coatings to objects as well as to create three-dimensional objects of silicon carbide-containing materials. In addition, it is also possible not only to coat objects or components but also to join them by means of materials containing silicon carbide or to repair damage in the form of material defects.

Particularly good results are obtained in the context of the present invention when powdery precursor materials are used. In this way, on the one hand, a high material application can be realized in a layer thickness, and on the other hand, powdery precursor materials can be moved towards the substrate surface, for example by means of a nozzle, and can be gasified and decomposed by, for example, laser radiation, without the decomposition products being deflected too strongly in their direction, so that a site-selective application is still possible.

In the context of the present invention, as previously stated, it is customary for the silicon carbide-containing material to be selected from optionally doped silicon carbide, optionally doped non-stoichiometric silicon carbide, silicon carbide alloys, and mixtures thereof. The production of silicon carbide, in particular doped stoichiometric silicon carbide from precursor compounds, in particular powdery precursor compounds, is known in principle and is practiced, for example, within the scope of German patent application 10 2015 105 085.4.

To date, however, it is not known that it is possible to deposit almost any silicon carbide-containing materials onto a substrate in a site-selective manner by decomposition of suitable precursor compounds and thus to create silicon carbide-containing objects or to coat objects with silicon carbide-containing materials.

In the context of the present invention, it is customary for the silicon carbide-containing material to be deposited as a layer on the substrate surface. The deposition of the silicon carbide-containing material in the form of a layer is achieved in particular by carrying out the site-selective deposition continuously or discontinuously at all desired locations of the substrate surface to be coated.

A continuous deposition can thereby be obtained, for example, by continuously carrying out the method, wherein the location of the deposition changes continuously, for example, by selectively and continuously directing and moving a particle beam onto the substrate surface. Discontinuous deposition, on the other hand, is achieved, for example, by interrupting the deposition of silicon carbide-containing material and restarting the deposition at a different location on the substrate surface.

Usually, the silicon carbide-containing material is deposited on the substrate surface with a layer thickness in the range of 0.01 to 5 mm, in particular 0.05 to 2 mm, preferably 0.1 to 1 mm. By applying material with the above-mentioned layer thicknesses, on the one hand three-dimensional objects made of silicon carbide-containing materials can be obtained in a short time by means of additive manufacturing, and on the other hand thin and nevertheless resistant coatings with silicon carbide-containing materials are also possible. At the same time, almost any objects can also be joined by means of silicon carbide-containing materials.

In the context of the present invention, it has been well proven if the precursor material, in particular the powdery precursor material, is moved in finely divided form, in particular in the form of at least one particle beam, in the direction of the substrate and is gasified and decomposed by the action of energy, in particular laser radiation, before or on impacting the substrate, or in that the gaseous decomposition products are moved in the direction of the substrate, in particular in the form of a particle beam.

In the context of the present invention, a particle beam is to be understood as a directed stream of particles or particulates with a preferably constant cross-section, which preferably travels linearly. In the context of the present invention, the precursor materials or the decomposition products may be moved in one or more particle beams towards the substrate surface and meet, for example, in a focal point, e.g. the light beam of a laser, or on the substrate surface. The particle beam or beams is or are preferably directed towards the substrate surface.

In the context of the present invention, it is thus possible for the starting compounds to be moved in finely divided form, preferably in the form of a finely divided powder, in particular a powder beam, in the direction of the substrate surface and to be gasified and decomposed by the action of energy, in particular by the action of a laser beam, before, in particular immediately before or on impacting the substrate surface. In this way, the decomposition products are generated in the immediate proximity of the surface to which they are applied and can be deposited on the cooler substrate surface in preferably single-crystal form. Alternatively, it is also possible for the decomposition products to be moved, for example by a nozzle, in the direction of the substrate surface and applied thereto, wherein the decomposition products deposit at least in part on the substrate surface as the desired silicon carbide-containing material. However, there is always a risk here that larger agglomerates will already form in the gas phase and a less dense and homogeneous surface will be obtained.

In the context of the present invention, it may be provided that the particle beam comprises a cross-section in the range of 0.1 to 2 mm², in particular 0.2 to 1.5 mm², preferably 0.5 to 1.2 mm². More preferably, the particle beam comprises a cross-section of 1 mm².

In the context of the present invention, it is usually provided that the energy input is by thermal energy, in particular temperature increase, in particular by means of resistance heating, electric arc or radiant energy, preferably electric arc or radiant energy, more preferably by laser radiation.

Now, as far as the energy input is concerned, it has been well proven if the energy input, in particular by means of laser radiation, takes place with a resolution of 0.1 to 150 μm, in particular 1 to 100 μm, preferably 10 to 50 μm. In this way, a high energy input can be ensured in a narrowly limited space so that the precursors are completely gasified or decomposed.

A special feature of the method according to the present invention is in particular that it does not require any subsequent sintering steps, i.e. within the scope of the present invention the precursors are selected and in particular adapted to the process performance in such a way that a homogeneous, compact three-dimensional body is obtained directly from the gas phase, which does not have to be subjected to sintering.

In the context of the present invention, it is preferably the case that the precursor material, in particular the powdery precursor material, or the gaseous decomposition products is or are moved in the direction of the substrate by means of at least one nozzle. By the use of a nozzle it is in particular possible to obtain a sharply defined particle jet, preferably of gaseous particles or of powder particles, which are applied to the substrate surface in a site-selective manner. Particularly preferably, the nozzle is a powder nozzle or a gas nozzle.

The nozzle can be arranged either coaxially to a laser beam, for example, or laterally. In the coaxial arrangement, the laser beam and nozzle are usually located in a processing head or assembly, wherein the laser beam is directed almost perpendicularly to the substrate surface and the particle beam intersects it or several particle beams intersect the axis of the laser beam at a focal point. In the lateral arrangement, the laser beam is also typically arranged and movable perpendicular to the substrate surface, wherein a stream of particles is sprayed laterally into the axis of the laser beam.

As previously stated, the use of powdery precursor materials is preferred, wherein, however, gaseous or liquid precursor materials may also be used.

In the context of the present invention, it is usually provided that the powdery precursor material is moved in the direction of the substrate in the form of a powder beam, or that the liquid precursor material is moved in atomized form or as a liquid beam in the direction of the substrate, but preferably always in the form of a particle beam. Furthermore, it is possible that the gaseous precursor material is moved towards the substrate in the form of a gas beam. Alternatively, it is also possible that the gaseous decomposition products are moved in the direction of the substrate in the form of a gas beam.

The method according to the invention is suitable for the production of a large number of three-dimensional objects or for coating objects with silicon carbide-containing materials. In the context of the present invention, it is in particular preferred if the method is used to build up a three-dimensional silicon carbide-containing object layer by layer and/or for joining at least two components. The method according to the invention can thus on the one hand be a generative manufacturing process, but on the other hand can also be used as a joining process for joining objects or for repairing objects.

According to a particularly preferred embodiment of the present invention, the method is laser deposition melting or a method similar to laser deposition melting, in which the precursor materials are gasified and/or decomposed before or until contact with the substrate surface.

In the context of the present invention, it is preferred if the precursor material, in particular the powdery precursor material, is gasified and decomposed by laser radiation in proximity to the substrate surface, in particular in immediate proximity to the substrate surface. In this way, side reactions and undesired agglomerations are in particular prevented. In the context of the present invention, moreover, the substrate is heated only extremely slightly by the energy introduced, in particular by the laser beam, so that, on the one hand, it is possible to apply the silicon carbide-containing material as stress-free as possible.

It is usually provided that the gasification and decomposition of the powdery starting material and the deposition of the silicon carbide-containing material, preferably the entire method, is carried out in a protective gas atmosphere. In this way, undesired oxidation by oxygen is prevented.

If the method according to the invention is carried out in a protective gas atmosphere, it has been well proven if the method is carried out in a nitrogen and/or argon atmosphere, preferably an argon atmosphere. The method according to the invention is generally carried out in a protective gas atmosphere, so that in particular carbon-containing precursor compounds are not oxidized. If the method is carried out in an argon atmosphere, it is generally also an inert gas atmosphere, since argon does not react with the precursor compounds under the process conditions. If nitrogen is used as the inert gas, silicon nitrides in particular can also be formed. This may be desirable, for example, in the case of additional mixed doping of the silicon carbide with nitrogen.

However, if incorporation of nitrogen into the silicon carbide or into the silicon carbide-containing compound is not desired, the method according to the invention is carried out in an argon atmosphere.

In accordance with a preferred embodiment, it is thereby provided that the particle beam and/or the particle beams is or are surrounded by a stream of protective gas. The particle streams are thus surrounded by a stream of protective gas, which prevents a reaction with the surrounding atmosphere. In this way, it is also possible, for example, to coat larger objects by means of silicon carbide-containing material, which cannot easily be transferred into a chamber filled with inert gas.

In particular, the method according to the invention permits the simple production of virtually any silicon carbide-containing material—in particular from non-stoichiometric silicon carbides to silicon carbide-containing alloys for high-performance ceramics—from a wide range of precursor materials.

Suitable precursor materials are described in more detail below.

In the context of the present invention, for example, it may be envisaged that precursor materials are used which are either mixtures of liquid and/or gaseous carbon and silicon sources, i.e. compounds which release carbon or silicon or reactive intermediates under reaction conditions, or liquid solutions or dispersions which comprise the carbon and silicon sources.

If liquid and/or gaseous carbon sources are used as precursor materials in the present invention, it may be provided that the liquid and/or gaseous carbon source is selected from alkanes, amines, alkyl halides, aldehydes, ketones, carboxylic acids, amides, carboxylic acid esters and mixtures thereof, in particular C1- to C8-alkanes, primary and secondary C₁- to C₄-alkylamines, C₁- to C₈-alkyl halides, C₁- to C₈-aldehydes, C₁- to C₈-ketones, C₁- to C₈-carboxylic acids, C₁- to C₈-amides, C₁- to C₈-carboxylic acid esters and mixtures thereof.

Particularly good results are obtained in this context if the gaseous and/or liquid carbon source is selected from C₁- to C₈-alkanes, in particular C₁- to C₄-alkanes, and mixtures thereof. In the context of the present invention, it is thus preferred if the gaseous or liquid carbon source is a short-chain and thus highly volatile alkane. In particular, when oxygen-containing functional groups are used, care must be taken to ensure that the excess of carbon is so high that carbon is always oxidized to carbon monoxide or carbon dioxide and not, for example, silicon is oxidized to silicon dioxide or silicon dioxide is immediately reduced again by carbon, since silicon dioxide would significantly disrupt the structure and function of the silicon carbide-containing fibers or foams.

In the context of the present invention, it has also been well proven if the liquid and/or gaseous silicon source is selected from silanes, siloxanes and mixtures thereof, preferably silanes.

When siloxanes are used as precursors in the context of the present invention, if suitable siloxanes are selected, it is possible for the siloxane(s) to be both the carbon source and the silicon source and no other precursors need be used except for any doping or alloying reagents.

Preferably, however, solid, in particular powdery, precursor materials are used in the present invention. The solid precursor materials are usually in the form of a precursor granulate containing

at least one silicon source
at least one carbon source and
optionally precursors for doping and/or alloying elements.

In the case of precursor granules, the silicon source is usually selected from silane hydrolysates and silicic acids and mixtures thereof. In the context of the present invention, the silicon source, i.e. the precursor of the silicon in the silicon carbide-containing compound, is obtained in particular by hydrolysis of tetraalkoxysilanes, whereby in the precursor granules the silicon is preferably in the form of silicic acid or silane hydrolysates.

As far as the carbon source in the precursor granules is concerned, this is usually selected from the group of sugars, in particular sucrose, glucose, fructose, invert sugar, maltose; starch; starch derivatives and organic polymers, in particular phenol-formaldehyde resin, resorcinol-formaldehyde resin, and mixtures thereof and/or reaction product thereof, in particular sugars and/or reaction products thereof. Particularly preferably, the carbon source is selected from sugars and their reaction products, wherein sucrose and/or invert sugar and/or their reaction products are preferably used. Also, in the case of the carbon source, not only the actual reagent but also its reaction product can be used.

When the precursor granulate is used to produce a (stoichiometric) silicon carbide, the composition typically contains
(A) the silicon source in amounts of 40 to 60 wt. %, preferably 45 to 55 wt. %, based on the composition,
(B) the carbon source in amounts of 40 to 60 wt. %, preferably 45 to 55 wt. %, based on the composition, and
(C) optionally precursors of doping elements.

The precursors for the doping elements are usually contained in the precursor granules only in very small amounts, in particular in the ppm range.

When the precursor granulate is used to produce a non-stoichiometric silicon carbide, the composition typically contains
(A) the silicon source in amounts of 60 to 90 wt %, in particular 65 to 85 wt. %, preferably 70 to 80 wt %, based on the composition,
(B) the carbon source in amounts of 10 to 40 wt. %, in particular 15 to 35 wt %, preferably 20 to 30 wt %, based on the composition, and
(C) optionally precursors for doping elements.

Precursor granules comprising the carbon source and the silicon source in the aforementioned quantity ranges are excellent for reproducibly producing non-stoichiometric silicon carbides with an excess of silicon.

If the precursor granulate is used for the production of a silicon carbide alloy, the composition typically contains
(A) the silicon source in amounts of 5 to 40 wt %, in particular 5 to 30 wt. %, preferably 10 to 20 wt %,
(B) the carbon source in amounts of 10 to 60 wt. %, in particular 15 to 50 wt %, preferably 20 to 50 wt. %, and
(C) one or more precursors for alloying elements in amounts of 5 to 70 wt %, in particular 5 to 65 wt %, preferably 10 to 60 wt. %,
   in each case based on the composition.

A preferred precursor granulate is obtainable from a precursor solution or a precursor dispersion. In this context, it is particularly preferred if the precursor granulate is obtainable by a sol-gel method or by drying a sol. In sol-gel methods, solutions or finely divided solid-in-liquid dispersions are usually produced, which are converted by subsequent aging and the condensation processes occurring in the process to a gel containing larger solid particles.

After drying the gel or the sol, a particularly homogeneous composition, in particular a suitable precursor granulate, can be obtained, with which, when suitable stoichiometry is selected, the desired silicon carbide-containing compounds can be obtained by the action of energy in additive manufacturing.

Furthermore, it may be provided that the precursor granulate is converted to a reduced precursor granulate by thermal treatment under reductive conditions. The reductive thermal treatment usually takes place in an inert gas atmosphere, wherein in particular the carbon source, preferably a sugar-based carbon source, reacts with oxides or other compounds of silicon as well as possible further compounds of other elements, reducing the elements and forming volatile oxidized carbon and hydrogen compounds, in particular water and CO₂, which are removed via the gas phase.

Precursor granules can in particular be prepared by a sol-gel method, wherein
(i) in a first method step a solution or dispersion, in particular a sol, containing
   (I) at least one silicon-containing compound,
   (II) at least one carbon-containing compound,
   (III) at least one solvent or dispersant, and
   (IV) optionally doping and/or alloying reagents,
   is produced,
(ii) in a second method step following the first method step (i), the solution or dispersion is reacted, in particular aged to a gel, and
(iii) in a third method step following the second method step (ii), the reaction product from the second method step (ii), in particular the gel, is dried and, if necessary, comminuted.

A method for the production of a suitable precursor granulate for the production of silicon carbide by means of a sol-gel process is mentioned, for example, in German patent application DE 10 2015 105 085.4.

In the context of the present invention, a solution is to be understood as a single-phase system in which at least one substance, in particular a compound or its building blocks, such as ions, are homogeneously distributed in a further substance. In the context of the present invention, a dispersion is to be understood as an at least two-phase system, wherein a first phase, namely the dispersed phase, is present distributed in a second phase, the continuous phase. The continuous phase is also called dispersion medium or dispersant. In particular with sols or also with polymeric compounds, the transition from a solution to a dispersion is often fluid, so that it is no longer possible to distinguish clearly between a solution and a dispersion.

As far as the selection of the solvent or dispersant in method step (a) is concerned, this can be selected from all suitable solvents or dispersants. Usually, however, the solvent or dispersant in method step (a) is selected from water and organic solvents and mixtures thereof, preferably mixtures thereof. In particular in the case of mixtures containing water, inorganic hydroxides, in particular metal hydroxides and silicic acids, are often formed by hydrolysis reaction of the starting compounds, which subsequently condense, so that the method can be carried out in the form either of a sol-gel process or else is stopped at the stage of a sol.

Furthermore, it may be provided that the solvent is selected from alcohols, in particular methanol, ethanol, 2-propanol, acetone, ethyl acetate and mixtures thereof. Particularly preferably in this context, the organic solvent is selected from methanol, ethanol, 2-propanol and mixtures thereof, wherein ethanol is more preferably.

The aforementioned organic solvents are miscible with water in wide ranges and in particular also suitable for dispersing or dissolving polar inorganic substances.

For the production of the sol or gel, mixtures of water and at least one organic solvent, in particular mixtures of water and ethanol, are preferably used as solvents or dispersants. In this context, it is preferred if the solvent or dispersant comprises a ratio by weight of water to organic solvent of 1:10 to 20:1, in particular 1:5 to 15:1, preferably 1:2 to 10:1, more preferably 1:1 to 5:1, particularly preferably 1:3. By the ratio of water to organic solvent, on the one hand, the hydrolysis rate, in particular of the silicon-containing compound as well as of the alloying reagents, can be adjusted, and on the other hand, the solubility and reaction rate of the carbon-containing compound, in particular of the carbon-containing precursor compound, such as sugars, can also be adjusted.

Furthermore, it is more preferably the case that in the method for the production of the precursor granulate in method step (i) the silicon-containing compound is selected from silanes, silane hydrolysates, orthosilicic acid as well as mixtures thereof, in particular silanes. Orthosilicic acid and also its hydrolysis products can be obtained in the context of the present invention, for example, from alkali metal silicates whose alkali metal ions have been exchanged for protons by ion exchange. However, alkali metal compounds are not used, if possible, in the context of the present invention, since they are incorporated into the resulting precursor granulate, in particular when a sol-gel method is used or when the sol is dried, and are consequently also found in the silicon carbide-containing compound. However, alkali metal doping is generally not desired in the context of the present invention. However, if this should be desired, suitable alkali metal salts, for example of the silicon-containing compound or also alkali phosphates, can be used.

Particularly good results are obtained in the context of the present invention if silanes, in particular tetraalkoxysilanes and/or trialkoxyalkylsilanes, preferably tetraethoxysilane, tetramethoxysilane or triethoxymethylsilane are used as the silicon-containing compound in method step (i), since these compounds react by hydrolysis in aqueous medium to give orthosilicic acids or their condensation products or highly crosslinked siloxanes and the corresponding alcohols.

As far as the carbon-containing compound is concerned, it has been well proven that in method step (i) the carbon-containing compound is selected from the group of sugars, in particular sucrose, glucose, fructose, invert sugar, maltose; starch; starch derivatives and organic polymers, in particular phenol-formaldehyde resin, resorcinol-formaldehyde resin, and mixtures thereof. Particularly good results are obtained in the context of the present invention when in method step (i) the carbon-containing compound is used in an aqueous solution or dispersion.

In particular, when the carbon-containing compound is used in an aqueous solution or dispersion, the carbon-containing compound is usually introduced in a small amount of the solvent or dispersant, in particular water, provided for the production of the precursor granulate in method step (i). In this context, particularly good results are obtained when the carbon-containing compound is used in a solution containing the carbon-containing compound in amounts of 10 to 90 wt. %, in particular 30 to 85 wt. %, preferably 50 to 80 wt. %, more preferably 60 to 70 wt. %, based on the solution or dispersion of the carbon-containing compound.

In particular, it is also possible, for example, for catalysts, in particular acids or bases, to be added to the solution or dispersion of the carbon-containing compound, in order, for example, to accelerate the inversion of sucrose and to achieve better reaction results.

With regard to the temperatures at which method step (i) is carried out, it has been well proven that method step (i) is carried out at temperatures in the range of 15 to 40° C., in particular 20 to 30° C., preferably 20 to 25° C.

Furthermore, it is possible that in method step (ii) the temperatures are slightly increased compared to method step (i) in order to accelerate the reaction of the individual components of the solution or dispersion, in particular the condensation reaction during the aging of the sol to the gel.

Particularly good results are obtained in this context if method step (ii) is carried out at temperatures in the range of 20 to 80° C., in particular 30 to 70° C., preferably 40 to 60° C.

It has been particularly well proven in this context if method step (ii) is carried out at 50° C.

As far as the time period is concerned for which method step (ii) is carried out, this can vary depending on the respective temperatures, the solvents used and the precursor compounds used. Usually, however, method step (ii) is carried out for a period of 15 minutes to 20 hours, in particular 30 minutes to 15 hours, preferably 1 to 10 hours, more preferably 2 to 8 hours, particularly preferably 2 to 5 hours. Within the aforementioned time periods, a complete reaction of the sol to a gel is usually observed if the method is carried out as a sol-gel method.

Now, as far as the amounts of the individual components in method step (ii) relative to each other are concerned, these can vary within wide ranges depending on the respective intended use. For example, precursor compositions for stoichiometric silicon carbide or non-stoichiometric silicon carbide comprise completely different compositions and proportions of the individual components than compositions intended for the production of silicon carbide alloys.

Also, when selecting the individual compounds, in particular the doping reagents or alloying reagents, care must be taken to ensure that they can be processed into homogeneous granules with a carbon source and a silicon source, which can react in generative manufacturing processes to form silicon carbide-containing compounds.

In particular, it is preferable to ensure that the doping and/or alloying reagents are decomposed or cleaved under the action of energy in such a way that the desired elements de-sublimate as reactive particles to form the desired alloy, while the remaining constituents of the compound react as far as possible to form stable gaseous substances, such as water, CO, CO₂, HCl, etc., which can be easily removed via the gas phase. Furthermore, the compounds used should comprise sufficiently high solubilities in the solvents used, in particular in ethanol and/or water, to be able to form finely divided dispersions or solutions, in particular sols, and may not react with other constituents of the solution or dispersion, in particular the sol, to form insoluble compounds during the production process. In addition, the reaction rates of the individual reactions taking place must be coordinated with one another, since hydrolysis, condensation and, in particular, gelation, which may be carried out, must proceed undisturbed in advance of granulate formation. Furthermore, the reaction products formed may not be sensitive to oxidation and should also not be volatile.

Furthermore, it may be provided that the solution or dispersion contains at least one doping and/or alloying reagent. If the solution comprises a doping and/or alloying reagent, it has been well proven if the solution or dispersion comprises the doping or alloying reagent in amounts of 0.000001 to 60 wt. %, in particular 0.000001 to 45 wt. %, preferably 0.000005 to 45 wt. %, more preferably 0.00001 to 40 wt. %, based on the solution or dispersion.

If the solution or dispersion comprises a dopant reagent, the solution or dispersion typically comprises the dopant reagent in amounts of 0.000001 to 0.5 wt. %, preferably 0.000005 to 0.1 wt %, more preferably 0.00001 to 0.01 wt. %, based on the solution or dispersion.

If the solution or dispersion contains an alloying reagent, it is usually provided that the solution or dispersion contains the alloying reagent in amounts of 5 to 60 wt. %, in particular 10 to 45 wt. %, preferably 15 to 45 wt %, more preferably 20 to 40 wt. %, based on the solution or dispersion.

Turning now to the chemical nature of the doping reagent, it may be selected from suitable doping elements. Preferably, the doping reagent or doping element is selected from elements of the third and fifth main groups of the periodic table. Preferably, the doping reagent is selected from compounds of an element of the third or fifth main group of the periodic table of elements, which is soluble in the solvent or dispersant. The doping reagent is usually selected from nitric acid, ammonium chloride, melamine, phosphoric acid, phosphonic acids, boric acid, borates, boron chloride, indium chloride and mixtures thereof.

If doping with nitrogen is intended, the solution may contain nitric acid, ammonium chloride or melanin. If doping with phosphorus is intended, phosphoric acid or phosphates or phosphonic acids can be used, for example.

If doping with boron is intended, boric acids, borates or boron salts, such as boron trichloride, are used, for example.

If doping with indium is intended, water-soluble indium salts, such as indium chloride, are usually used as doping reagents.

If the solution or dispersion contains an alloying reagent, the alloying reagent is usually selected from in the solvent or dispersant soluble compounds of Al, Ti, V, Cr, Mn, Co, Ni, Zn, Zr and mixtures thereof. According to a more preferred embodiment of the present invention, the alloying reagent is selected from chlorides, nitrates, acetates, acetylacetonates and formates of Al, Ti, V, Cr, Mn, Co, Ni, Zn, Zr and mixtures thereof.

If a stoichiometric silicon carbide SiC, which is optionally doped, is to be obtained, particularly good results are obtained if the solution or dispersion in the first method step contains the silicon-containing compound in amounts of 10 to 40 wt %, in particular 12 to 30 wt. %, preferably 15 to 25 wt. %, more preferably 17 to 20 wt. %, based on the solution or dispersion.

Similarly, according to this embodiment, it may be provided that the solution or dispersion comprises the carbon-containing compounds in amounts of 6 to 40 wt. %, in particular 8 to 30 wt. %, preferably 10 to 25 wt. %, more preferably 12 to 20 wt %, based on the solution or dispersion.

Furthermore, in accordance with this embodiment, it may be provided that the solution or dispersion comprises the solvent or dispersant in amounts of 20 to 80 wt %, in particular 30 to 70 wt %, preferably 40 to 60 wt. %, more preferably 45 to 55 wt. %, based on the solution or dispersion.

If the silicon carbide is to be doped, the solution or dispersion typically contains the doping reagent in amounts of 0.000001 to 0.5 wt. %, preferably 0.000005 to 0.1 wt %, more preferably 0.00001 to 0.01 wt %, based on the solution or dispersion.

If a non-stoichiometric silicon carbide is to be obtained, in particular with a molar excess of silicon, it has been well proven if the solution or dispersion in the first method step (a) contains the silicon-containing compound in amounts of 12 to 40 wt %, in particular 15 to 40 wt. %, preferably 18 to 35 wt. %, more preferably 20 to 30 wt. %, based on the solution or dispersion.

According to this embodiment, it may further be provided that the solution or dispersion comprises the carbon-containing compound in amounts of 6 to 40 wt. %, in particular 8 to 30 wt. %, preferably 10 to 25 wt. %, more preferably, 12 to 20 wt. %, based on the solution or dispersion.

Furthermore, in accordance with this embodiment, it may equally be provided that the solution or dispersion comprises the solvent or dispersant in amounts of 20 to 80 wt %, in particular 30 to 70 wt. %, preferably 40 to 60 wt %, more preferably 45 to 55 wt. %, based on the solution or dispersion.

If the non-stoichiometric silicon carbide is to be doped, it has been well proven if the solution or dispersion contains the doping reagent in amounts of 0.000001 to 0.5 wt. %, preferably 0.000005 to 0.1 wt %, preferably 0.00001 to 0.01 wt. %, based on the solution or dispersion.

If a silicon carbide alloy is to be produced, it has been well proven if the solution or dispersion in the first method step (a) contains the silicon-containing compound in amounts of 5 to 30 wt %, in particular 6 to 25 wt. %, preferably 8 to 20 wt. %, preferably 10 to 20 wt. %, based on the solution or dispersion.

Similarly, according to this embodiment, it is preferred if the solution or dispersion comprises the carbon-containing compound in amounts of 5 to 40 wt. %, preferably 6 to 30 wt. %, preferably 7 to 25 wt %, more preferably, 10 to 20 wt %, based on the solution or dispersion.

Furthermore, in accordance with this embodiment, it is preferred if the solution or dispersion comprises the solvent or dispersant in amounts of 20 to 70 wt %, in particular 25 to 65 wt %, preferably 30 to 60 wt. %, preferably 35 to 50 wt. %, based on the solution or dispersion.

It is advantageously provided that the solution or dispersion contains the alloying reagent in amounts of 5 to 60 wt. %, in particular 10 to 45 wt. %, preferably 15 to 45 wt %, more preferably 20 to 40 wt. %, based on the solution or dispersion.

Particularly preferably, the alloying reagent is selected from the corresponding chlorides, nitrates, acetates, acetylacetonates and formates of the corresponding alloying elements.

Turning now to the performance of method step (iii), it has been well proven if in method step (iii) the reaction product from method step (ii) is dried at temperatures in the range of 50 to 400° C., in particular 100 to 300° C., preferably 120 to 250° C., more preferably 150 to 200° C.

In this context, it has been well proven if the reaction product in method step (iii) is dried for a period of 1 to 10 hours, in particular 2 to 5 hours, preferably 2 to 3 hours.

In addition, it is possible for the reaction product to be comminuted in method step (iii), in particular following the drying process. In this context, it is preferred in particular if the reaction product is comminuted mechanically in method step (iii), in particular by grinding. Grinding processes can be used to specifically adjust the particle sizes required or advantageous for carrying out generative manufacturing processes. However, it is often also sufficient to mechanically stress the reaction product from method step (ii) during the drying process, for example by stirring, in order to set the desired particle sizes.

Preferably, a fourth method step (iv) following method step (iii) subjects the composition obtained in method step (iii) to a reductive thermal treatment so that a reduced composition is obtained. The use of a reduced composition which has been subjected to a reductive treatment has the advantage that a large number of possible and interfering by-products have already been removed. The resulting reduced precursor granulate is again significantly more compact and contains higher proportions of the elements that form the silicon carbide-containing compound.

If, following method step (iii), a reductive thermal treatment of the composition obtained in method step (iii) is carried out, it has been well proven if in method step (iv) the composition obtained in method step (iii) is heated to temperatures in the range from 700 to 1,300° C., in particular 800 to 1,200° C., preferably 900 to 1,100° C.

In this context, particularly good results are obtained when the composition obtained in method step (iv) is heated for a period of 1 to 10 hours, in particular 2 to 8 hours, preferably 2 to 5 hours. In the temperature ranges and the reaction durations mentioned, carbonization of the carbon-containing precursor material can in particular take place, which can significantly facilitate the subsequent reduction, in particular of metal compounds.

In general, method step (iv) is carried out in a protective gas atmosphere, in particular an argon and/or nitrogen atmosphere. In this way, oxidation of the carbon-containing compound in particular is prevented.

If the reductive thermal treatment of the precursor granules described above is provided in order to obtain reduced precursor granulate, the precursor compounds should not evaporate at the applied temperatures of up to 1,300, preferably up to 1,100° C., but must decompose selectively under the reductive thermal conditions to form compounds which can be converted selectively during production to the desired silicon carbide-containing compounds.

Alternatively, the method for the production of a precursor granulate can also be carried out in such a way that
(I) in a first method step, a solution or dispersion, in particular a sol, comprising the components
   (A) at least one silicon-containing compound,
   (B) at least one carbon-containing compound,
   (C) at least one solvent or dispersant, and
   (D) optionally doping and/or alloying reagents,
   is produced, and
(II) in a second method step following the first method step (i), the solvent or dispersant is removed.

This is because, as was surprisingly found, it is often possible to dispense with carrying out a sol-gel method. In particular, comparable precursor granules can often be obtained if the solvent or dispersant is removed after sol formation, for example in vacuo.

The precursor granules obtained in this way can be converted into a reduced precursor granulate by temperature treatment in the range from 400 to 800° C. The precursor granules obtained after sol formation by removing the solvent or dispersant correspond in their percentage distribution of the elements contained to the precursor granules obtained by a sol-gel method and can be processed like these.

The figures show according to

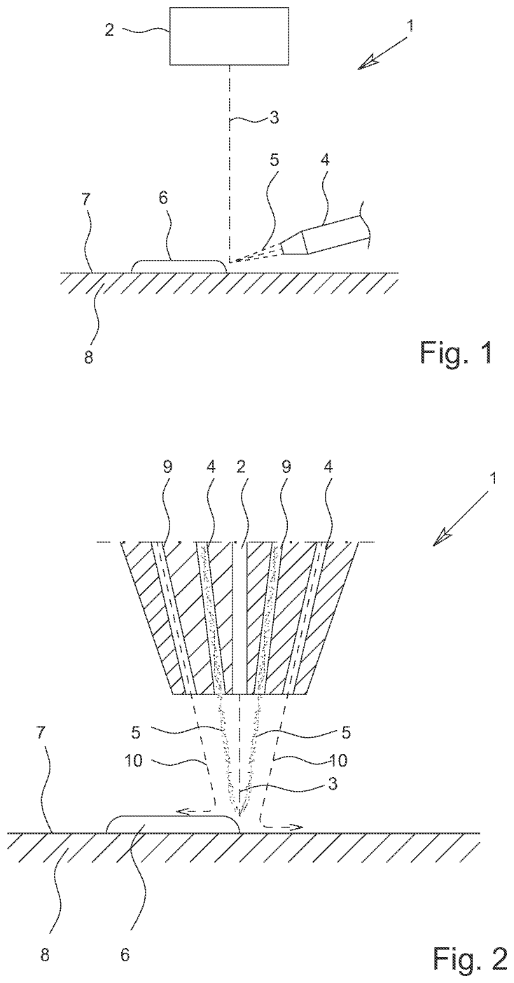

FIG. 1 an apparatus according to the invention for carrying out the method according to the invention with a powder feed arranged laterally to the laser beam,

FIG. 2 a section of an apparatus 1 according to the invention with coaxially arranged powder feeds and

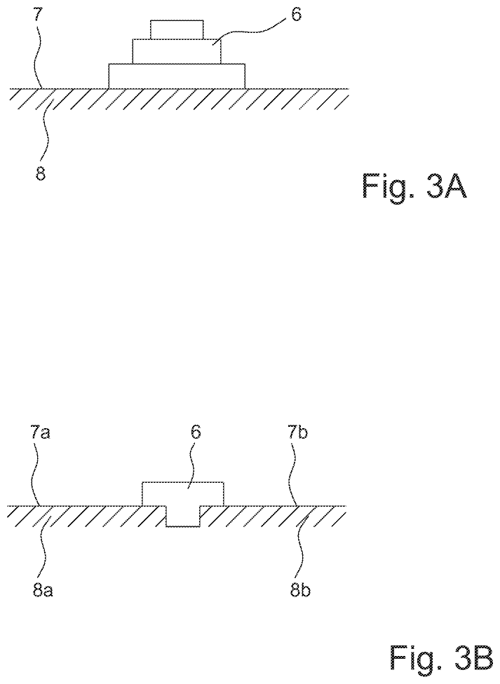

FIG. 3 according to Fig. A an example of the result of the method according to the invention in the form of a generated three-dimensional object and according to B an example of the result of the implementation of the method according to the invention as a joining process.

A further subject-matter of the present invention—according to a second aspect of the present invention—is a silicon carbide-containing object obtainable by the method described above.

With the method according to the present invention, objects containing silicon carbide can be produced by means of generative manufacturing. Equally, however, it is also possible for objects or articles to be coated with a silicon carbide-containing material or for parts to be joined by means of the method according to the invention.

For further details on the silicon carbide-containing object according to the invention, reference can be made to the above explanations on the method according to the invention, which apply accordingly with respect to the silicon carbide-containing object.

Finally, according to a third aspect of the present invention, a further subject-matter of the present invention is an apparatus for the site-selective deposition of silicon carbide-containing materials on a substrate surface, wherein the apparatus comprises
(a) at least one device for decomposing gaseous precursor materials or for gasifying and decomposing liquid or powdery precursor materials, wherein the precursor materials comprise at least one carbon source and at least one silicon source, and
(b) at least one device for generating at least one particle beam and/or for directing a particle beam onto the substrate surface.

It is essential in the context of the present invention that the gaseous decomposition products of precursor materials containing at least one silicon source and at least one carbon source are directed site-selectively and locally limited to a substrate surface, so that on the substrate surface silicon carbide-containing materials are deposited.

As already explained, the method according to the invention is preferably carried out as laser deposition welding or as a method based on laser deposition welding. For carrying out the method, apparatuses are preferably used which largely correspond to those for powder laser deposition welding. In particular, the best results are obtained in the present invention when the particle beam is a powder beam. This ensures that a relatively large amount of material is deposited on the substrate surface in a short time, and also that the energy of the laser beam is absorbed much better by the solid precursor material than, for example, by a gaseous starting material. As a result, heating of the substrate surface is largely avoided and good deposition of material containing silicon carbide on the substrate surface is achieved.

In the context of the present invention, as previously stated, it is preferably provided that the starting materials are decomposed only in the proximity of the substrate surface, which is most easily achieved by the use of powdered starting materials.

In the context of the present invention, it is advantageously provided that the device for generating a particle beam and/or for directing a particle beam onto a substrate surface is a nozzle, in particular a solid-matter nozzle, preferably a powder nozzle. As previously stated, in the context of the present invention, best results are obtained when the starting materials or the precursor materials are in powder form.

In the context of the present invention, it is further advantageously provided that the device for decomposition of gaseous starting compounds or for gasification and decomposition of liquid or powdery starting materials comprise means for generating high temperatures, in particular means for generating laser radiation or means for generating an electric arc.

By using an electric arc or laser radiation, preferably laser radiation, the starting materials can be easily decomposed in the proximity of the substrate surface.

According to a more preferred embodiment of the present invention, the device for decomposing gaseous precursor materials or for gasifying and decomposing liquid or powder precursor materials comprises means for generating laser radiation. Preferably, the device for decomposition of gaseous precursor compounds or for gasification and decomposition of liquid or powdery precursor materials is a laser.

Furthermore, it is usually provided that the apparatus comprises means for generating a protective gas atmosphere. To prevent undesired oxidation of the gaseous decomposition products by atmospheric oxygen, the method according to the invention is usually carried out in an inert gas atmosphere. Either it can be provided that a part of the apparatus, in particular the part containing the substrate, comprises a protective gas atmosphere. Alternatively and more preferably, however, it is provided that the particle beam, for example the powder beam, is surrounded by a protective gas and thus a protective gas atmosphere is generated locally, in particular in the region of the gasification and decomposition of the starting materials.

For further details, reference can be made to the above explanations on the further aspects of the invention, which apply accordingly with respect to the apparatus according to the present invention.

The subject-matter of the present invention is illustrated below by way of example and in a non-limiting manner by the figure description.

FIG. 1 shows an apparatus according to the invention with a device for gasification and/or decomposition of precursor materials, in particular a device 2 for generating laser beams 3. Furthermore, the apparatus 1 comprises at least one device 4 for generating a particle stream from gaseous, liquid or solid precursor materials 5. Preferably, the particle beam is formed by powdery precursor materials. However, all precursor materials have in common that they always comprise at least one silicon source and one carbon source as well as possibly also alloying elements or doping elements or compounds thereof.

The laser beams 3 and the particle beam of the precursor material 5 are directed onto the surface 7 of a substrate 8 in such a way that the laser beams 3 strike the particle beam in the immediate proximity of the substrate surface 7. As a result, the precursor materials 5 contained in the particle beam are decomposed or gasified and decomposed, thereby obtaining reactive fragments which are deposited as a desired silicon carbide material in the form of a layer of a silicon carbide-containing material 6 on the substrate surface 7.

The thickness of the layer of silicon carbide-containing material 6 may be between 0.01 to 5 mm, in particular 0.5 to 2 mm, preferably 0.1 to 1 mm.

The method according to the invention with the aid of the apparatus 1 thus permits a site-selective and locally sharply limited application of a layer 6 of a silicon carbide-containing material. By movement, in particular motion, of the substrate 8, or of the devices 2 and 4, either a three-dimensional object with a multilayer structure can be obtained or the substrate surface 7 can be coated in a desired manner with a layer of the silicon carbide-containing material 6.

FIG. 2 shows an alternative design of the apparatus 1 according to the invention. In particular, FIG. 2 shows a section of an apparatus 1. The apparatus 1 comprises a device 2 for gasification and/or decomposition of gaseous, liquid or powdery precursor materials 5, wherein preferably the device 2 for gasification and/or decomposition of the starting materials is designed in the form of a device for generating laser beams 2.

The apparatus 1 further comprises devices 4 for generating a particle beam, in particular from gaseous, liquid or powdery starting materials, in particular powdery starting materials. With the embodiments shown in FIG. 2, the devices 2 and 4 are integrated together in a nozzle head which is preferably designed to be movable, in particular designed to be movable.

The particle beam from the precursor material 5, in particular the particle beams 5, surround the laser beam 3 and cross it shortly before impacting the surface 7 of a substrate 8, whereby the precursor materials are decomposed and a layer of a silicon carbide-containing material 6 is deposited on the substrate surface 7.

The apparatus 1 further comprises means 9, in particular nozzles, for generating a protective gas atmosphere, in particular a stream of protective gas 10. The stream of protective gas 10 surrounds or envelops the particle beam(s) of the precursor material 5 and thus enables decomposition of the starting materials in a protective gas atmosphere, in particular an argon atmosphere.

Finally, FIG. 3 shows various possible applications of the apparatus 1 according to the invention and the method according to the invention. In particular, three-dimensional objects can be obtained by repeated application of layers of silicon carbide-containing material 6, as shown in alternative A. Similarly, it is also possible to bond components, in particular substrates 8a and 8b, via their surfaces, in particular their surfaces 7a and 7b, by applying the silicon carbide-containing material 6.

Reference signs:

| | |
|---|---|
| 1 | Apparatus |
| 2 | Device for generating laser beams |
| 3 | Laser beams |
| 4 | Device for generating a particle beam |
| 5 | Precursor material |
| 6 | Silicon carbide-containing material |
| 7 | Substrate surface |
| 8 | Substrate |

1. A method of applying silicon carbide-containing materials to a substrate surface, wherein
a gaseous, liquid or powdery precursor material containing a silicon source and a carbon source is gasified and/or decomposed by the action of energy and at least a part of the decomposition products are deposited site-selectively on the substrate surface as a silicon carbide-containing material.

2. The method according to claim 1, wherein the silicon carbide-containing material is selected from optionally doped silicon carbide, optionally doped non-stoichiometric silicon carbide, silicon carbide alloys and mixtures thereof.

3. The method according to claim 1, wherein the silicon carbide-containing material is deposited as a layer on the substrate surface.

4. The method according to claim 1, wherein the silicon carbide-containing material is deposited on the substrate with a layer thickness in the range of 0.01 to 5 mm, 0.05 to 2 mm, or 0.1 to 1 mm.

5. The method according to claim 1, wherein:
the powdery precursor material is moved in the form of at least one particle beam in the direction of the substrate surface, and is gasified and decomposed by the action of laser radiation before or on impacting the substrate, or
the gaseous decomposition products are moved in the direction of the substrate, in the form of at least one particle beam.

6. The method according to claim 5, wherein the powdery precursor material or the gaseous decomposition products is or are moved toward the substrate by means of at least one nozzle.

7. The method according to claim 5, wherein:
the powdery precursor material is moved in the direction of the substrate in the form of a powder beam, or
the liquid precursor material is moved in atomized form or as a liquid beam in the direction of the substrate, or
the gaseous precursor material or the gaseous decomposition products are moved in the direction of the substrate in the form of a gas beam.

8. The method according to claim 1, wherein the method is used for building up a three-dimensional silicon carbide-containing object layer by layer and/or for joining at least two components.

9. The method according to claim 1, wherein the method is laser deposition welding.

10. The method according to claim 9, wherein the powdery precursor material is gasified and decomposed by laser radiation in immediate proximity to the substrate surface.

11. The method according to claim 1, wherein the gasification and decomposition of the precursor material and the deposition of the silicon carbide-containing material is carried out in a protective gas atmosphere.

12. The method according to claim 5, wherein the particle beam or the particle beams is or are surrounded by a stream of protective gas.

13. A silicon carbide-containing object produced by the method of claim 1.

14. An apparatus for the site-selective deposition of silicon carbide-containing materials on a substrate surface,
wherein:
the apparatus comprises
(c) at least one device for decomposing gaseous precursor materials or for gasifying and decomposing liquid or powdery precursor materials, wherein the precursor materials comprise at least one carbon source and at least one silicon source, and
(d) at least one device for generating at least one particle beam and/or for directing a particle beam onto the substrate surface.

15. The apparatus according to claim 14, wherein the device for generating a particle beam and/or for directing a particle beam onto the substrate surface is a nozzle selected from a solid-matter nozzle and a powder nozzle.

16. The apparatus according to claim 14, wherein the device for decomposing gaseous precursor materials or for gasifying and decomposing liquid or powdery precursor materials comprises means for generating high temperatures, laser radiation or an electric arc.

17. The apparatus according to claim 16, wherein the device for decomposing gaseous precursor materials or for gasifying and decomposing liquid or powdery precursor materials comprises means for generating laser radiation.

18. The apparatus according to claim 14, wherein the apparatus comprises means for generating a protective gas atmosphere.
